(19) United States
(12) Patent Application Publication
(10) Pub. No.: US 2025/0308942 A1
(43) Pub. Date: Oct. 2, 2025

(54) METHOD OF FORMING A DIE PACKAGE AND DIE PACKAGE

(71) Applicant: Infineon Technologies AG, Neubiberg (DE)

(72) Inventors: Hui Kin Lit, Seremban 2 (MY); Chii Shang Hong, Bukit Katil (MY); Lee Shuang Wang, Bukit Baru (MY); Adbul Rahman Mohamed, Muar (MY)

(21) Appl. No.: 19/091,273

(22) Filed: Mar. 26, 2025

(30) Foreign Application Priority Data
Mar. 28, 2024 (DE) 102024109051.0

(51) Int. Cl. H01L 21/56; H01L 23/00; H01L 23/31

(52) U.S. Cl. CPC H01L 21/565; H01L 23/315; H01L 24/40; H01L 24/84; H01L 2224/40245; H01L 2224/84001

(57) ABSTRACT

A method of forming a die package is provided. The method may include arranging a stack including a die pad, a die, and a clip in a molding cavity, and, at least during an initial phase of filling the molding cavity with molding material, pressing the stack towards a bottom of the molding cavity with at least one pin contacting a top surface of the clip.

### TECHNICAL FIELD

Various embodiments relate generally to a method of forming a die package and die package.

### BACKGROUND

Some die packages that include a die pad/leadframe do not include a tie bar. These packages are also referred to as tiebarless packages. Such a concept may for example be common for high creepage packages in transistor outline (TO).

When forming such a die package, a positon of the die pad may usually be secured during a molding/encapsulation process by pressing, with a fixed or retractable pin at a location on the die pad towards a bottom of a mold cavity.

To maximize a chip size that fits in the package, an area that needs to be occupied on the die pad by the pin may be a constraint in package design that needs to be considered in terms of the allowable space.

In die packages where a separation between an intended position of the pin and an edge of the die is selected to be very tight, a positioning tolerance of the pin may cause a contact between the pin and the die, which may even cause a chipping of the die, possibly damaging the die.

### SUMMARY

A method of forming a die package is provided. The method may include arranging a stack including a die pad, a die, and a clip in a molding cavity, and, at least during an initial phase of filling the molding cavity with molding material, pressing the stack towards a bottom of the molding cavity with at least one pin contacting a top surface of the clip.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a flow diagram of a method of forming a die package in accordance with various embodiments;

FIGS. 2A and 2B show different schematic views of a stack for forming a die package in accordance with various embodiments;

FIG. 3A shows a schematic view of a stack for forming a die package in accordance with various embodiments;

FIG. 3B and FIG. 3C show different schematic views of a die package in accordance with various embodiments;

FIG. 4A shows a schematic view of a stack for forming a die package in accordance with various embodiments;

FIG. 4B and FIG. 4C show different schematic views of a die package in accordance with various embodiments;

FIG. 5 shows a flow diagram of a method of forming a die package in accordance with various embodiments; and

FIGS. 6A to 6E illustrate, as a sequence of schematic views, a method of forming a die package in accordance with various embodiments.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In various embodiments, pressing at least one retractable or fixed pin on a clip top (for example on a top of a wing design clip) instead of pressing on a die pad during an encapsulation process may provide more freedom of design and a maximizing of a size of a die area.

A design of the wing clip may be universal for a range of die sizes.

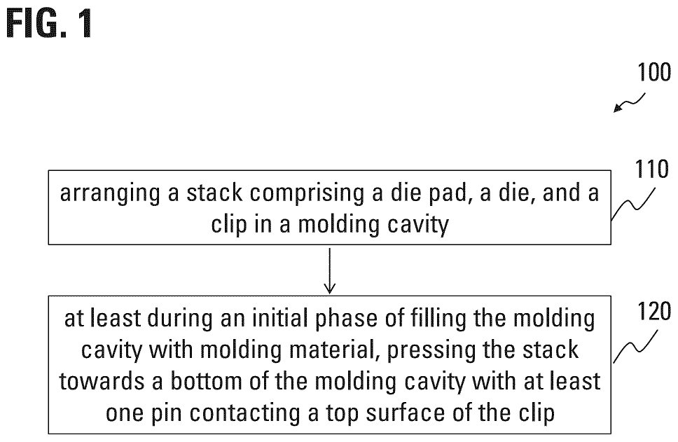

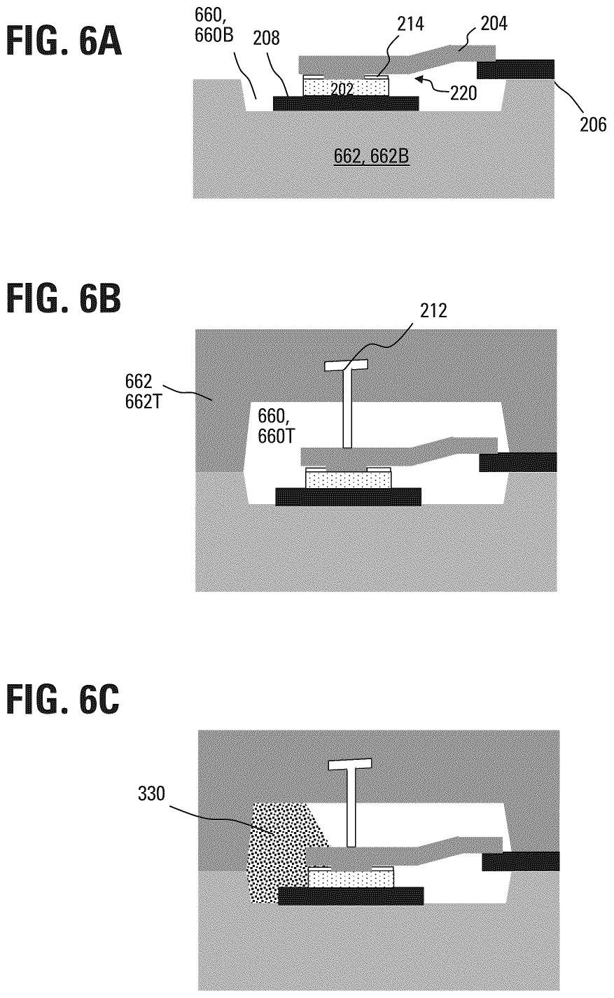

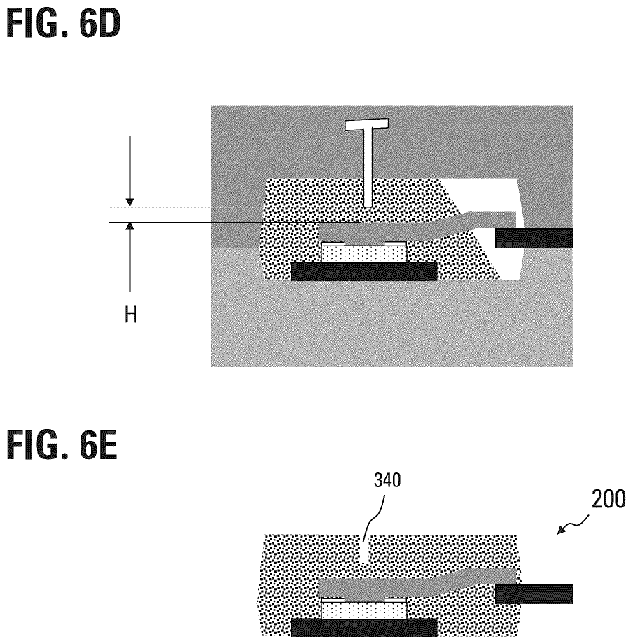

FIG. 1 shows a flow diagram 100 of a method of forming a die package in accordance with various embodiments, and FIGS. 6A to 6E illustrate, as a sequence of schematic views, a method of forming a die package 200 in accordance with various embodiments. To avoid crowding in the drawings, references of elements that repeatedly appear in different views are sometimes omitted.

The method may include arranging a stack 220 including a die pad 208, a die 202, and a clip 204 in a molding cavity 660 (in 110).

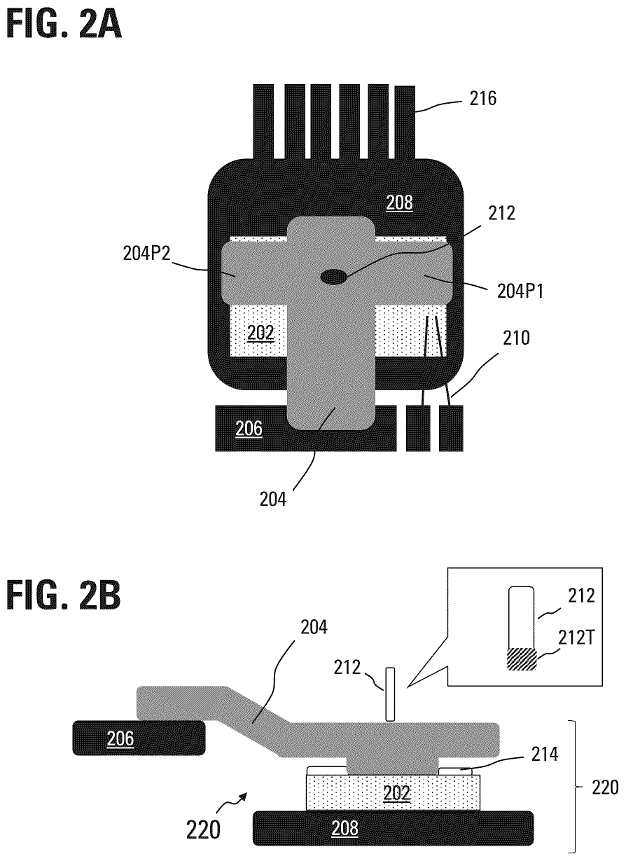

FIG. 6A illustrates an example of this process, and FIGS. 2A and 2B illustrate details of the stack 220 in two different views.

The die pad 208 may be configured essentially as known in the art, for example as a metal die pad 208, for example as a die pad 208 that may include or consist of copper and/or aluminum, and/or any other suitable material or material combination that is used in the art for die pads 208 in die packages. A thickness of die pad 208 may for example be in a range from about 500 μm to about 5 mm, for example from about 1 mm to about 3 mm.

The die 202 (which may also be referred to as chip) may in various embodiments be configured essentially as known in the art. The die 202 may be configured as a circuit element, for example a transistor, e.g., a MOSFET, or a diode, for example in a power application. The die 202 may include a plurality of contact pads. The die 202 may for example include a first contact pad on its bottom surface, and a second contact pad on its top surface. The first contact pad may contact the die pad 208, and the second contact pad may contact the clip 204. The die 202 may for example be configured for a vertical current through the die between the first contact pad and the second contact pad. The die 202 may optionally further include a third contact pad, e.g., a control pad, which may for example be arranged on the top surface of the die 202, for example in a surface area that is not covered by the clip 204.

Optionally, some areas of the die 202 that are not covered by the contact pads may be covered by an electrically insulating layer 214, e.g., by an organic material layer (e.g., an imide layer), an oxide layer, or the like.

The clip 204 may, except for optional features as described herein, be configured essentially as known in the art as a flat, three-dimensionally shaped elongated metal structure. The clip 204 may for example include or consist of copper and/or aluminum, and/or any other suitable material used in the art for clips in die packages.

The clip 204 may be arranged to contact (e.g., at or near a first end of the clip 204) the second contact pad on the top surface of the die 202. A second end of the clip 204, which may be the other distal end of the clip 204, may contact a lead 206 that may form an external contact of the die package 200.

The stack 220 may be arranged in the molding cavity 660, for example in a bottom portion 660B of a two-part molding cavity 660, with the die pad 208 contacting a bottom surface of the molding cavity 660, which may be formed by a top surface of a bottom part 662B of a, for example, two-part mold 662, 663B, 662T.

In order to keep the die pad 208 flat and to avoid molding material 330 from entering into a space that may be formed between the die pad 208 and the bottom part 662B of the mold 662, the stack 220 may, at least during an initial phase of filling the molding cavity 660 with molding material, be pressed against the top surface of the bottom part 662B of the mold such that the bottom surface 208 of the die pad it is in contact and contiguous with the top surface 662B. The pressing of the stack 220 is accomplished using at least one pin 212 contacting a top surface of the clip 204.

A corresponding example is illustrated in FIG. 6B, which also shows the mold 662, and also in FIGS. 2A and 2B, which do not show the mold, but the pin 212, with details on the pin 212, which may for example be provided with a soft tip 212T, in other words, a tip 212T that may have a hardness that is lower than a hardness of the clip 204 material. For example, the tip 212T may be elastic, for example be formed of a polymer material, for example a silicone-based or rubber material that does not stick to the molding material 330, or for example a metal that is softer than the metal of the clip 204.

A force of the pin 212 pressing on the clip 204 may be about 3 kg, and thus in a range that is similar to a diffusion soldering bond force. For this reason, and also because the clip has a relatively large contact area on the die (e.g., more or less the complete die pad), a risk of causing a die crack by pressing the pin 212 onto the clip 204 may be low.

Nevertheless, the elastic/soft tip 212T may in various embodiments help adjust a maximum force on the clip 204.

The pin 212 may in various embodiments be a fixed pin, which may remain in place until the molding process is completed, and may only be removed together with the mold 662 or after the mold 662.

The pin 212 may in various embodiments be a retractable pin, which may remain in place only during an initial phase of the molding process, and may be partially removed while the molding process is still on-going.

If the pin 212 is retracted during the molding, it may be ensured that a position of the die pad 208 in relation to the bottom part of the mold 662B is sufficiently fixed to continuously avoid a bending of the die pad 208 and/or molding material 330 entering between the die pad 208 and the bottom part of the mold 662B. For example, the molding material 330 that was introduced into the molding cavity 660 during the initial phase of the molding process may already be partially cured, and or a level of the molding material 330 in the molding cavity 660 may be sufficiently high to add enough pressure for keeping the die stack 220, and the die pad 208 with it, in place. For example, the pin 212 may be retracted when a top surface of the die pad is covered by the molding material 330. Alternatively, the pin 212 may also be retracted at the end of the molding process.

The molding material 330 may for example include a polymer material, for example a thermoplastic material, polyimide, a resin, and/or any other suitable molding material commonly used in the art.

The molding process is visualized in FIGS. 6C and 6D. The illustration of the molding material 330, which appears to indicate a high-viscosity molding material 330 that is introduced into the molding cavity 660 from a side, is to be understood as exemplary. In various embodiments, depending on a viscosity of the molding material 330, a speed of addition of the molding material, whether or not an at least partial curing is performed during the filling of the molding cavity, etc., a configuration of the molding material 330 in the molding cavity 660 may differ from the arrangements shown in FIGS. 6C and 6D. For example, rather than filling the left portion of the molding cavity 660 while leaving the right portion of the molding cavity 660 free from the molding material 330, the molding material 330 may for example start filling up the molding cavity 660 from the bottom upwards.

The initial phase of the filling the molding cavity 660 may for example be completed when the die pad 208 is covered by the molding material 330 (and, optionally, the molding material 330 is at least partially cured), or when both the die pad 208 and the die 202 are enclosed in or covered by the molding material, or when also the clip 204, for example at least a portion of the clip 204 directly above the die 202, is covered by the molding material 330, or at any other suitable point during the molding process where it is sufficiently ensured that the stack 220 maintains its position.

FIG. 6D visualizes a situation in which the retractable pin 212 is retracted to a height H above a top surface of the clip 204. FIG. 6E shows the die package 200 in accordance with various embodiments that may result after releasing the die package 200 from the (e.g., two-part) mold and removing the pin 212 (either together with the top part 662T of the mold 662, before that, or after that).

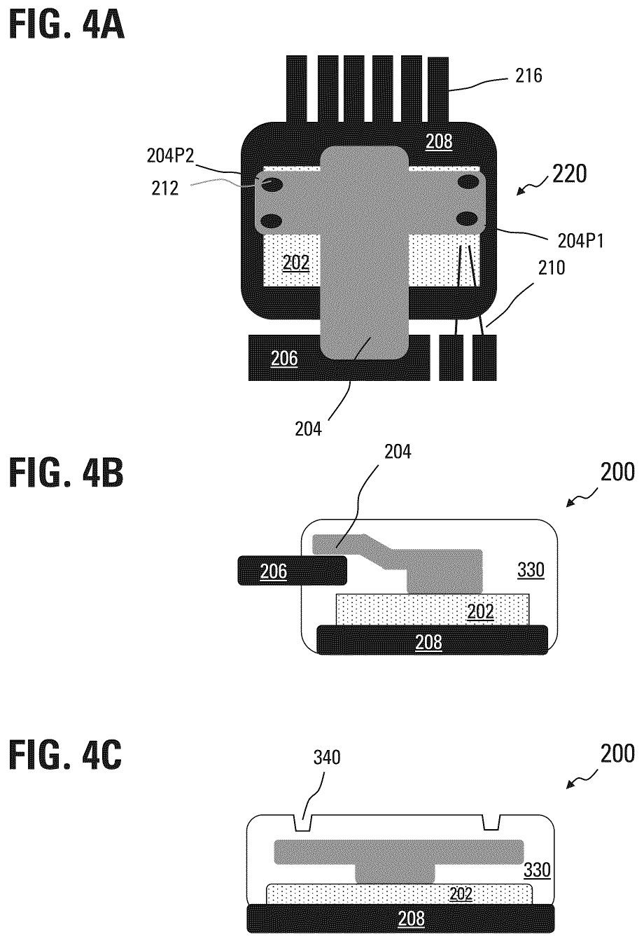

Similarly, FIG. 4A shows a stack 220 with pins 212 arranged to press on protruding portions 204P1, 204P2 of the clip 204. The resulting die package 200 shown in FIGS. 4B and 4C includes holes 340 in the molding material 330 where the pin 212 resided within the molding material 330.

The retractable pin 212 may for example be used for chip packages 200 where it is undesirable to have a surface (e.g., an electrically conductive surface) where the pin 212 pressed on the clip 204 exposed in the final die package 200.

In the blind hole 340 left behind by the retractable pin 212, a bottom may be formed by the molding material 330. In other words, the blind hole 340 may extend only partially through the molding material 330 from a top surface of the die package 200 towards the clip 204.

In various embodiments, the fixed pin 212 may be used, for example for chip packages 200 where it is it does not matter if the surface (e.g., an electrically conductive surface) where the pin 212 pressed on the clip 204 is exposed in the final die package 200, or where this may even be desired, for example for cooling or other purposes.

In various embodiments, the blind hole 440 formed by removing the (in particular fixed, but optionally retractable) pin 212 may be filled after the completion of the molding process.

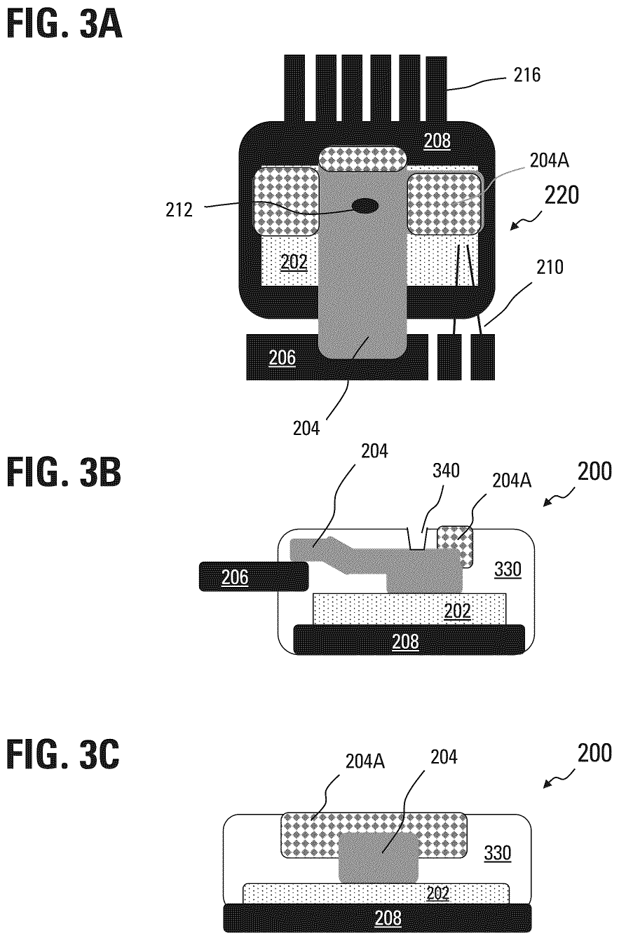

FIG. 3A shows a stack 220 with a pin 212 arranged to press on a portion of the clip 204 that is arranged above the contact pad of the die 202. The resulting die package 200 shown in FIGS. 3B and 3C may include a blind hole 340 in the molding material 330 that may for example extend all the way down to the top surface of the clip 204.

Already a clip 204 that may be configured like in the prior art may increase a design freedom, in particular regarding a positioning of the at least one pin 212.

Even in a case where the at least one pin 212 includes a plurality of pins 212, there may be plenty of room on the back surface of the clip 204.

Since no space on the die pad 208 needs to be reserved for the positioning of the at least one pin 212, an area of the die 202 may be maximized. For example, the die 202 may be configured to cover for example at least 80%, at least 90%, or for example at least 95% of the die pad 208.

The clip 204 may in various embodiments have protrusions 204P1, 204P2 (also referred to as “wings”) that may extend away from a central portion of the clip 204 to opposite directions. Exemplary embodiments of clips 204 having such protrusions 204P1, 204P2 are shown in FIGS. 2A and 2B, 3A to 3C, and 4A to 4C, with the protrusions 204P1, 204P2 visible in FIGS. 2A, 3A, 3C, 4A, and 4C. The clip 204 of the die package 200 formed according to FIGS. 6A to 6C may or may not have the protrusions 204P1, 204P2.

In various embodiments, the clip 204 may have a smaller thickness in the protrusions 204P1, 204P2 than in the central portion, and/or may be vertically displaced upwards. The protrusions 204P1, 204P2 may for example not be in contact with a top surface of the die 202. In other words, when the clip 204 is arranged to contact the top surface of the die 202, e.g. the second contact pad, respective bottom surfaces of the protrusions 204P1, 204P2 may have a distance to a top surface of the die 202 and/or to the die pad 208.

The protrusions 204P1, 204P2 may in various embodiments be configured symmetrically with respect to a longitudinal axis of the clip 204.

This may allow for a symmetrical placement of the plurality of pins 212 if they are placed on the protrusions 204P1, 204P2, either only on the protrusions 204P1, 204P2 or in addition to one or more pins 212 arranged on the central portion of the clip 204. An example of pins 212 placed (symmetrically) on the protrusions 204P1, 204P2 is shown in FIG. 4A.

The symmetrical distribution of the pins 212 on the protrusions 204P1, 204P2 may allow for a comparatively even force to be applied on the clip 204. A tilting of the die pad 208 and molding material 330 getting arranged between the die pad 208 and the bottom part 662B of the mold 662 (also referred to as mold flashes) may be avoided even more effectively, for example completely.

In various embodiments, a thickness of the clip 204 may be in a range from 100 μm to 2 mm, for example from about 500 μm to about 1 mm. The clip 204 may have an essentially constant thickness over its whole area, or may have at least a first portion having a first thickness and a second portion having a second thickness.

For example, the clip 204 may have a first (larger) thickness in the portion of the clip 204 that contacts die 202, and a second (smaller) thickness in the remaining portion of the clip 204, for example the portion extending towards the lead 206, and optionally the protrusions 204P1, 204P2.

In various embodiments, the clip may have additional portions 204A that may be configured to add to a thickness of portions of the clip 204, wherein the resulting thickness may be configured to result in the additional portions 204A being exposed at a top of the die package 200, for example for a top-side cooling.

The additional portions 204A may for example be arranged in a central portion of the clip 204 and/or on the protrusions 204P1, 204P2.

In FIGS. 3A to 3C, the additional portions 204A are, for clarity, shown with a different pattern than the main part of the clip 204, but they may be integrally formed and for example include or consist of the same material as the rest of the clip 204.

In various embodiments, the clip 204 having the at least one additional portion 204A may have a first (e.g., largest) thickness in a contact portion of the clip 204 where the additional portion 204A is formed, optionally a second thickness where the additional portion 204A is formed on the protrusions 204P1, 204P2, optionally a third thickness in a contact portion of the clip 204 where no additional portion 204A is formed, and further optionally a fourth thickness in a portion that extends towards the lead 206. For example, the clip 204 may have a thickness of about 500 μm in the portion that extends towards the lead 206, and a thickness of 900 μm in the portion that includes the protrusions 204P1, 204P2 and the additional portion 204A.

Considering the different thicknesses and the three-dimensional shape of the clip 204, the plurality of pins 212 may optionally contact the clip 204 at different heights within the molding cavity 660 before and/or during at least an initial phase of the molding process. Further optionally, the pins 212 may be retracted at different points in the molding process and/or to different final heights in the molding cavity 660. As a result, the blind holes 440 formed in the resulting die package 220 may extend, from the top surface of the die package 200, to different depths.

For example, before the molding, a plurality of pins 212 may be distributed over the protrusions 212P1, 212P2 and the central portion of the clip 204, for example like adding the pin 212 of FIG. 3A to the pins 212 of FIG. 4A. The plurality of pins 212 may ensure the flatness of the die pad 208, avoid its tilting and mold flashes. After the initial phase of the molding process, for example, the pins 212 on the protrusions 212P1, 212P2 may be removed, while the pin 212 on the central portion of the clip 204 may, at least initially, be left in place, and either retracted at a later point of the molding process, or left in place until the molding process is completed.

Any other arrangement of pins 212, retraction sequence, or combination of fixed pins 212 and retractable pins 212 may be employed as considered suitable for the die package 200 to be obtained.

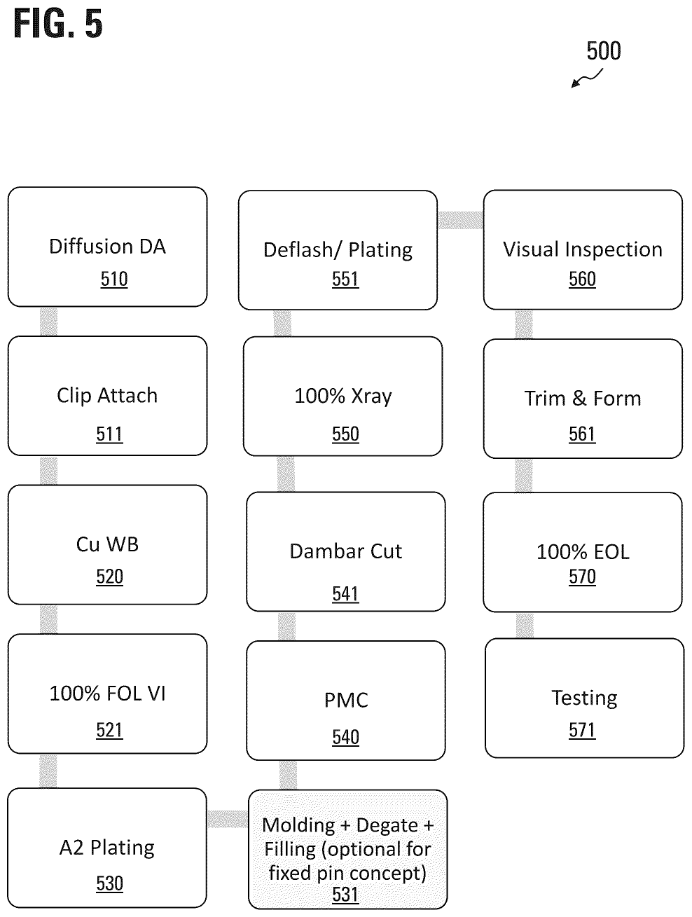

FIG. 5 shows a flow diagram 500 of a method of forming a die package in accordance with various embodiments. Some examples for standard processes are provided (e.g., diffusion soldering, A2 plating, etc.) that may be replaced by other standard processes as known in the art.

The die 202 may be attached to the die pad 208, for example by diffusion soldering (in 510). The clip 204 may be attached to the die (in 511), e.g., to the top surface of the die 202, for example by (e.g., diffusion) soldering. Wire bonding may subsequently be applied (in 520), for example for connecting die contact pads with leads 206 by (e.g., copper) wires 210. This may conclude the front end of line (FOL) processing (in 521). In preparation for the packaging, an A2 plating may be applied (in 530) as an adhesion promoter for increasing an adhesion between surfaces of the stack 220 and the molding material 330 to be applied next (in 531). The above described details of the embodiments mostly address this process. Optionally, excessive molding material may be removed (also referred to as degating). Further optionally, blind holes 440 formed when the pin(s) was/were removed, in particular in case of fixed pins 212, may be filled, e.g. by additional molding material. Thereby, the plastic molded case PMC (and, except for a few final touches and quality control tests, the die package 200) is completed (in 540). A subsequent dambar cutting process (in 541) may be used for trimming/aligning/shaping the die package 200 and its leads 206. An X-ray inspection (in 550) may be used for ensuring that a quality of the previous processes was sufficient. In a subsequent deflashing process, excessive material may be applied for a removal of excess material, and a protective plating may be applied (in 551). As a further quality control, the die package 220 may be visually inspected (in 560), and be subjected to a final trimming and forming process (in 561). This may complete the end-of-line process (in 570), and the die package 200 may be subjected to functional testing (in 571).

Various examples will be illustrated in the following.

Example 1 is a method of forming a die package. The method may include arranging a stack including a die pad, a die, and a clip in a molding cavity, and, at least during an initial phase of filling the molding cavity with molding material, pressing the stack towards a bottom of the molding cavity with at least one pin contacting a top surface of the clip.

In Example 2, the subject-matter of Example 1 may optionally further include, after the initial phase, retracting the at least one pin.

In Example 3, the subject-matter of Example 2 may optionally include that the initial phase is concluded when a top surface of the die pad is covered by the molding material.

In Example 4, the subject-matter of any of Examples 1 to 3 may optionally further include, at least during the initial phase of filling the molding cavity with molding material at least partially curing the molding material.

In Example 5, the subject-matter of Example 1 may optionally further include retracting the at least one pin only after the filling the molding cavity with molding material is completed.

In Example 6, the subject-matter of any of Examples 1 to 5 may optionally include that the at least one pin includes a plurality of pins.

In Example 7, the subject-matter of Example 6 may optionally include that the plurality of pins is distributed over the top surface of the clip evenly and/or symmetrically with respect to a longitudinal axis of the clip.

In Example 8, the subject-matter of any of Examples 1 to 7 may optionally include that the clip includes a contact portion configured to contact the die and protrusion portions extending away from the contact portion in opposite directions.

In Example 9, the subject-matter of Examples 6 and 8 may optionally include that at least one of the plurality of pins is arranged on each of the protrusion portions.

In Example 10, the subject-matter of any of Examples 1 to 9 may optionally include that the pin includes a tip having a hardness that is lower than a hardness of the clip. The tip may for example be elastic.

In Example 11, the subject-matter of any of Examples 1 to 10 may optionally include that the filling of the mold cavity continues until the clip is completely covered.

In Example 12, the subject-matter of any of Examples 1 to 10 may optionally include that, after the filling of the mold cavity is completed, a top portion of the clip remains free from the molding material.

In Example 13, the subject-matter of any of Examples 6 to 12 may optionally include that the plurality of pins press the stack at different heights.

In Example 14, the subject-matter of any of Examples 6 to 13 may optionally include that the plurality of pins are retracted at different stages of the filling process.

Example 15 is a die package. The die package may include a stack including a die pad, a die, and a clip, molding material at least partially encapsulating the stack, and at least one blind hole extending only part way through the molding material from a top of the die package towards the clip, or extending fully through the molding material, with a bottom surface of the blind hole being formed by a top surface of the clip.

In Example 16, the subject-matter of Example 15 may optionally include that the at least one blind hole includes a plurality of blind holes.

In Example 17, the subject-matter of Example 16 may optionally include that the plurality of blind holes extend to the same depth or to different depths in the molding material.

Example 18 is a die package. The die package may include a stack including a die pad, a die, and a clip, and molding material at least partially encapsulating the stack, wherein a bottom surface of the die pad is flat and free from the molding material.

In Example 19, the subject-matter of Example 18 may optionally include that a total volume extending between a contact surface and a top of the die package is free from blind holes, wherein the contact surface is formed as an interface of a top surface of the die pad and the molding material.

Example 20 is a die package. The die package may include a stack including a die pad, a die, and a clip, and molding material at least partially encapsulating the stack, wherein the clip includes a contact portion contacting the die and protrusion portions extending away from the contact portion in opposite directions.

Example 21 is a die package. The die package may include a stack including a die pad, a die, and a clip, and molding material at least partially encapsulating the stack, wherein the die covers at least 80%, optionally at least 90%, of a surface area of the die pad.

In Example 22, the subject-matter of any of Examples 18 to 21 may optionally further include at least one blind hole extending at least partially through the molding material from a top surface of the die package towards the clip.

In Example 23, the subject-matter of any of Examples 15 to 22 may optionally include that a thickness of die pad is in a range from 500 μm to 5 mm.

In Example 24, the subject-matter of any of Examples 15 to 23 may optionally include that a thickness of the clip is in a range from 100 μm to 2 mm.

In Example 25, the subject-matter of any of Examples 15 to 24 may optionally include that the clip includes a first portion having a first thickness and a second portion having a second thickness that is different from the first thickness.

In Example 26, the subject-matter of any of Examples 15 to 25 may optionally include that the clip is completely encapsulated by the molding material.

In Example 27, the subject-matter of any of Examples 15 to 25 may optionally include that a portion of the clip is exposed at a top surface of the die package.

In Example 28, the subject-matter of Example 16 may optionally include that the plurality of blind holes is distributed over the clip surface evenly and/or symmetrically with respect to a longitudinal axis of the clip.

In Example 29, the subject-matter of any of Examples 15 to 28 may optionally include that the clip includes a contact portion configured to contact the die and a plurality of protrusion portions extending away from the contact portion in opposite directions.

In Example 30, the subject-matter of any of Examples 15 to 29 may optionally include that at least one of the plurality of blind holes is arranged on each of the protrusion portions.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of forming a die package, the method comprising:
arranging a stack comprising a die pad, a die, and a clip in a molding cavity;
at least during an initial phase of filling the molding cavity with a molding material, pressing the stack towards a bottom of the molding cavity with at least one pin contacting a top surface of the clip.

2. The method of claim 1, further comprising:
after the initial phase, retracting the at least one pin.

3. The method of claim 2,
wherein the initial phase is concluded when a top surface of the die pad is covered by the molding material.

4. The method of claim 1, further comprising:
at least during the initial phase of filling the molding cavity with the molding material, at least partially curing the molding material.

5. The method of claim 1, further comprising:
retracting the at least one pin only after the filling the molding cavity with the molding material is completed.

6. The method of claim 1,
wherein the at least one pin comprises a plurality of pins.

7. The method of claim 6,
wherein the plurality of pins is distributed over the top surface of the clip evenly and/or symmetrically with respect to a longitudinal axis of the clip.

8. The method of claim 6,
wherein at least one of the plurality of pins is arranged on each of the protrusion portions.

9. The method of claim 6,
wherein the plurality of pins presses the stack at different heights.

10. The method of claim 6,
wherein the plurality of pins is retracted at different stages of the filling process.

11. The method of claim 1,
wherein the clip comprises a contact portion configured to contact the die and a plurality of protrusion portions extending away from the contact portion in opposite directions.

12. The method of claim 1,
wherein the at least one pin comprises a tip having a hardness that is lower than a hardness of the clip.

13. The method of claim 1,
wherein the filling of the mold cavity continues until the clip is completely covered.

14. The method of claim 1,
wherein after the filling of the mold cavity is completed, a top portion of the clip remains free from the molding material.

15. A die package, comprising:
a stack comprising a die pad, a die, and a clip;
a molding material at least partially encapsulating the stack; and
at least one blind hole extending only part way through the molding material from a top of the die package towards the clip, or extending fully through the molding material, with a bottom surface of the blind hole being formed by a top surface of the clip.

16. The die package of claim 15,
wherein the at least one blind hole comprises a plurality of blind holes.

17. The die package of claim 16,
wherein the plurality of blind holes extends to different depths in the molding material.

18. The die package of claim 16,
wherein the plurality of blind holes is distributed over the clip surface evenly and/or symmetrically with respect to a longitudinal axis of the clip.

19. The die package of claim 15,
wherein the clip comprises a contact portion configured to contact the die and a plurality of protrusion portions extending away from the contact portion in opposite directions.

20. The die package of claim 19,
wherein at least one of the plurality of blind holes is arranged on each of the protrusion portions.

21. The die package of claim 15,
wherein the clip comprises a first portion having a first thickness and a second portion having a second thickness that is different from the first thickness.

22. The die package of claim 15,
wherein the clip is completely encapsulated by the molding material.

23. The die package of claim 15,
wherein a portion of the clip is exposed at a top surface of the die package.
